(19) United States
(12) Patent Application Publication
(10) Pub. No.: US 2019/0055651 A1
(43) Pub. Date: Feb. 21, 2019

(54) SHOWER HEAD AND VACUUM PROCESSING APPARATUS

(71) Applicant: ULVAC, INC., Chigasaki-shi, Kanagawa (JP)

(72) Inventors: YOSUKE JINBO, Chigasaki-shi, Kanagawa (JP); YOSHIAKI YAMAMOTO, Chigasaki-shi, Kanagawa (JP); HIRONORI CHATANI, Chigasaki-shi, Kanagawa (JP); OSAMU NISHIKATA, Chigasaki-shi, Kanagawa (JP); TORU KIKUCHI, Chigasaki-shi, Kanagawa (JP)

(21) Appl. No.: 16/078,869

(22) PCT Filed: Sep. 15, 2017
(86) PCT No.: PCT/JP2017/033502

§ 371 Date: Aug. 22, 2018

(30) Foreign Application Priority Data
Dec. 13, 2016 (JP) 2016-241087

(51) Int. Cl. C23C 16/455; H01J 37/32; H01L 21/3065; H05H 1/46

(52) U.S. Cl. CPC C23C 16/45565; H01J 37/3244; H01J 2237/3322; H01J 37/32596; H05H 1/46; H01L 21/3065

(57) ABSTRACT

[Problem] To make an in-plane variation of a plasma density uniform.

[Solution] A shower head according to an embodiment of the present technology includes a head body and a shower plate. The head body has an inner space. The shower plate includes a plurality of gas injecting ports communicated with the inner space, a gas injecting surface on which gas is injected from the plurality of gas injecting ports, and a plurality of hole portions disposed on the gas injecting surface. The shower plate is configured in such a manner that surface areas of the plurality of hole portions are radially gradually increased from a center of the gas injecting surface.

### TECHNICAL FIELD

The present technology relates to a shower head and a vacuum processing apparatus.

### BACKGROUND ART

One of discharge methods used in a film formation process or an etching process is a method of using capacitively coupled plasma (CCP). For example, in a CVD (Chemical Vapor Deposition) apparatus using this method, a cathode and an anode are disposed to face each other. On the anode, a substrate is disposed, and electric power is input to the cathode. Then, the capacitively coupled plasma is generated between the cathode and the anode, and thus a film is formed on the substrate. Further, as the cathode, a shower head may be used on which multiple gas injecting ports are provided in order to uniformly supply discharge gas onto the substrate in some cases (for example, see Patent Literature 1).

### CITATION LIST

### Patent Literature

Patent Literature 1: Japanese Patent Application Laid-open No. 2005-328021

### DISCLOSURE OF INVENTION

### Technical Problem

However, in the capacitively coupled method using the shower head, as the sizes of the cathode and the anode are increased, an in-plane variation of a plasma density on the substrate may be increased in some cases. As a result, an in-plane variation of film quality of a film to be formed on the substrate may be increased in some cases.

In view of the circumstances as described above, an object of the present technology is to provide a shower plate and a vacuum processing apparatus which make the in-plane variation of the plasma density more uniform.

### Solution to Problem

To achieve the above object, a shower head according to an embodiment of the present technology includes a head body and a shower plate. The head body has an inner space. The shower plate includes a plurality of gas injecting ports communicated with the inner space, a gas injecting surface on which gas is injected from the plurality of gas injecting ports, and a plurality of hole portions disposed on the gas injecting surface. The shower plate is configured in such a manner that surface areas of the plurality of hole portions are radially gradually increased from a center of the gas injecting surface.

In the shower head, the shower plate includes the plurality of gas injecting ports and the plurality of hole portions, the surface areas of which are radially gradually increased from the center of the gas injecting surface on the gas injecting surface. As a result, by using the shower head, the in-plane variation of the plasma density is more uniform.

In the shower head, the gas injecting surface may include a center region and a plurality of regions which are disposed concentrically with respect to the center region and surround the center region. In two of the regions adjacent to each other, the surface area of each of the plurality of hole portions disposed on the region opposite to the center region may be larger than the surface area of each of the plurality of hole portions disposed on the region on the center region side.

With the shower head as described above, in the two regions which surround the center region and are adjacent to each other, the surface area of each of the plurality of hole portions disposed on the region opposite to the center region is larger than the surface area of the plurality of hole portions disposed on the region on the center region side. As a result, with the use of the shower head, the in-plane variation of the plasma density is more uniform.

In the shower head described above, an inner diameter of each of the plurality of hole portions disposed on the region opposite to the center region may be the same as an inner diameter of each of the plurality of hole portions disposed on the region on the center region side.

With the shower head as described above, in the two regions that surround the center region and are adjacent to each other, the inner diameter of each of the plurality of hole portions disposed on the region opposite to the center region is the same as the inner diameter of each of the plurality of hole portions disposed on the region on the center region side. As a result, with the use of the shower head, a hollow cathode discharge is difficult to be caused, and the in-plane variation of the plasma density is more uniform.

In the shower head described above, a depth of each of the plurality of hole portions disposed on the region opposite to the center region may be deeper than a depth of each of the plurality of hole portions disposed on the region on the center region side.

With the shower head as described above, in the two regions that surround the center region and are adjacent to each other, the depth of each of the plurality of hole portions disposed on the region opposite to the center region is deeper than the depth of each of the plurality of hole portions disposed on the region on the center region side. As a result, with the use of the shower head, the in-plane variation of the plasma density is more uniform.

In the shower head described above, the center region may further include a plurality of hole portions. A surface area of each of the plurality of hole portions disposed on the center region may be smaller than a surface area of each of the plurality of hole portions disposed on the region adjacent to the center region.

With the shower head as described above, the plurality of hole portions are also disposed on the center region, and the surface area of each of the plurality of hole portions disposed on the center region is smaller than the surface area of each of the plurality of hole portions disposed on the region adjacent to the center region. As a result, with the use of the shower head, the in-plane variation of the plasma density is more uniform.

In the shower head described above, a part of the plurality of hole portions disposed on the region opposite to the center region may be disposed on the region on the center region side. A part of the plurality of hole portions disposed on the region on the center region side may be disposed on the region opposite to the center region.

With the shower head as described above, in the two regions that surround the center region and are adjacent to each other, the part of the plurality of hole portions disposed on the region opposite to the center region is disposed on the region on the center region side. Further, the part of the plurality of hole portions is disposed on the region on the center region side is disposed on the region opposite to the center region. As a result, with the use of the shower head, the in-plane variation of the plasma density is more uniform.

To achieve the object described above, a vacuum processing apparatus according to an embodiment of the present technology includes a vacuum chamber, a shower head, and a support. The vacuum chamber is capable of maintaining a depressurized state. The shower head includes the head body and the shower plate. The support is caused to face the shower head and is capable of supporting a substrate.

The vacuum processing apparatus includes the shower head. As a result, with the use of the vacuum processing apparatus, the in-plane variation of the plasma density is more uniform.

### Advantageous Effects of Invention

As described above, according to the present technology, the shower plate and the vacuum processing apparatus which make the in-plane distribution of the plasma density more uniform are provided.

### BRIEF DESCRIPTION OF DRAWINGS

FIG. 1(a) is a schematic cross sectional view showing a vacuum processing apparatus according to this embodiment. FIG. 1(b) is a schematic cross sectional view showing a part of a shower plate according to this embodiment.

FIG. 2(a) is a schematic cross sectional view showing a plasma analysis model of a plasma analysis according to this embodiment. FIGS. 2(b) to 2(d) are schematic cross sectional views showing a plasma analysis result and graphs showing plasma densities according to this embodiment.

FIG. 3 A graph showing a relationship between a depth of a hole portion and the plasma density according to this embodiment.

FIG. 4(a) is a schematic plan view showing the shower plate according to this embodiment. FIG. 4(b) is a schematic plan view showing a region surrounded by a broken line 222d of FIG. 4(a). FIGS. 4(c) to 4(f) are schematic cross sectional views each showing a hole portion of the shower plate according to this embodiment.

FIG. 5(a) is a schematic plan view of a substrate on which a film is formed by a substrate processing apparatus according to this embodiment. FIG. 5(b) is a schematic graph showing a film thickness distribution of a film according to a comparison example. FIG. 5(c) is a schematic graph showing a film thickness distribution of a film according to this embodiment.

FIG. 6 A schematic graph showing a film stress distribution according to this embodiment and the comparison example.

FIG. 7 Schematic graphs showing relationships between deposition conditions and an optimal value of the depth of the hole portion in an outermost region.

FIG. 8(a) is a schematic plan view showing another embodiment of a gas injecting surface of the shower plate according to this embodiment. FIG. 8(b) is a schematic plan view showing another embodiment of sectioning the shower plate according to this embodiment.

### MODE(S) FOR CARRYING OUT THE INVENTION

Hereinafter, an embodiment of the present technology will be described with reference to the drawings. To the drawings, XYZ-axis coordinates are introduced in some cases.

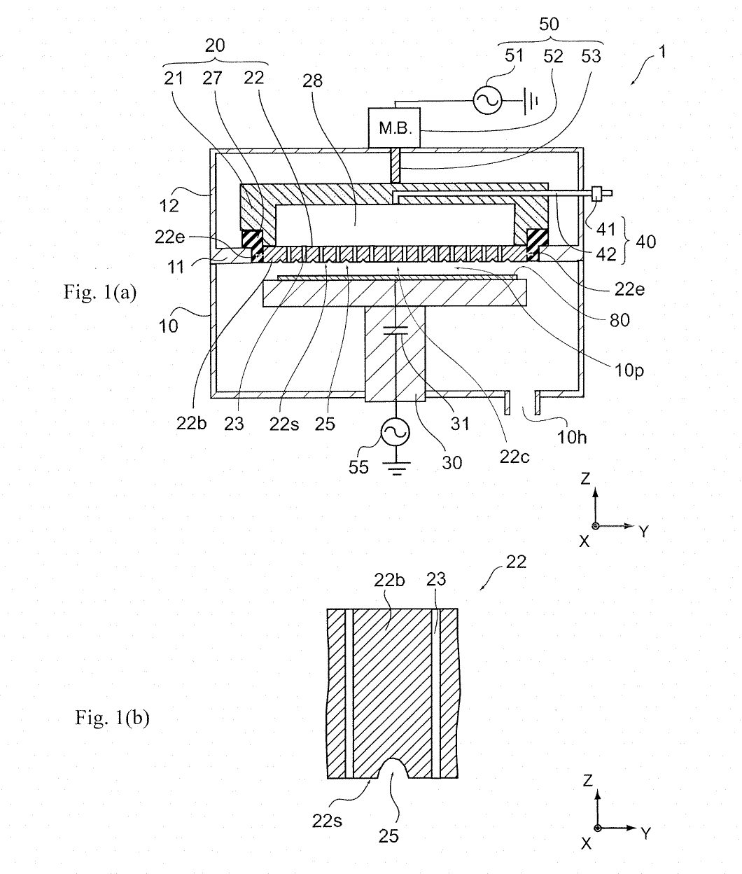

FIG. 1(a) is a schematic cross sectional view showing a vacuum processing apparatus according to this embodiment. FIG. 1(b) is a schematic cross sectional view showing a part of a shower plate according to this embodiment.

A vacuum processing apparatus 1 according to this embodiment is provided with a vacuum chamber 10, a support portion 11, a lid portion 12, a shower head 20, a support 30, a gas supply source 40, and power supply means 50, 55. The vacuum processing apparatus 1 combines a deposition means for forming a film on a substrate 80 by a plasma CVD (Chemical Vapor Deposition) method and an etching means for removing the film formed on the substrate 80 by dry etching.

In the vacuum processing apparatus 1, discharge plasma is formed between the shower head 20 and the support 30 by a capacitively coupled method, for example. The discharge plasma is formed by glow discharge, for example. A space between the shower head 20 and the support 30 is treated as a plasma forming space 10p in this embodiment. In the case where the vacuum processing apparatus 1 functions as a plasma CVD apparatus, for example, the shower head 20 functions as a cathode, and the support 30 functions as an anode. Further, in the case where the vacuum processing apparatus 1 functions as an etching apparatus of RIE (Reactive Ion Etching) or the like, for example, the shower head 20 functions as the anode, and the support 30 functions as the cathode.

The vacuum chamber 10 surrounds the support 30. The lid portion 12 faces the vacuum chamber 10. The support portion 11 is attached to the lid portion 12. A vacuum pump (not shown) such as a turbo molecular pump is connected to the vacuum chamber 10 through a gas exhaust port 10h, for example. With this configuration, a depressurized state between the shower head 20 and the support 30 can be maintained. For example, in an example of FIG. 1(a), a space surrounded by the shower head 20, the vacuum chamber 10, and the support portion 11 is maintained to be in the depressurized state by a vacuum pump. A space surrounded by the lid portion 12, the shower head 20, and the support portion 11 may include the atmosphere or may be in the depressurized state. The lid portion 12 functions as a shield box which shields high frequency wave input to the shower head 20. In the case where the space surrounded by the lid portion 12, the shower head 20, and the support portion 11 is maintained to be in the depressurized state, it is possible to regard the vacuum chamber 10 and the lid portion 12 as a vacuum chamber in combination. In this case, at least a part of a space in the vacuum chamber can be maintained to be in the depressurized state. Further, in the vacuum chamber 10, a manometer (not shown) which measures a pressure in the vacuum chamber 10 is provided.

The shower head 20 includes a head body 21, a shower plate 22, and an insulation member 27. The shower head 20 is supported by the support portion 11 of the vacuum chamber 10 via the insulation member 27. With this configuration, the shower head 20 is insulated from the vacuum chamber 10. Further, the shower head 20 can be removed from the vacuum processing apparatus 1.

The head body 21 includes an inner space 28. Into the inner space 28, discharge gas is introduced via a gas introduction tube 42 provided in the head body 21. A gas introduction port of the gas introduction tube 42 is located on the center of the inner space 28, for example. With this configuration, the discharge gas is supplied into the inner space 28 uniformly. The number of gas introduction ports is not limited to one, and a plurality of gas introduction ports may be provided.

The shower plate 22 is connected to the head body 21 so as to be closely attached thereto. The shower plate 22 includes a plate base member 22b, a plurality of gas injecting ports 23, a gas injecting surface 22s, and a plurality of hole portions 25. The plurality of gas injecting ports 23 respectively pass through the plate base member 22b. The plurality of gas injecting ports 23 are respectively communicated with the inner space 28.

A surface of the plate base member 22b which is opposite to the inner space 28 serves as the gas injecting surface 22s in the shower plate 22. The discharge gas is injected from the gas injecting surface 22s via the plurality of gas injecting ports 23 from the inner space 28.

In this embodiment, in addition to the plurality of gas injecting ports 23, the plurality of hole portions 25 are provided in the shower plate 22. The plurality of hole portions 25 are disposed on the gas injecting surface 22s. The plurality of hole portions 25 are respectively disposed on the gas injecting surface 22s so as not to be overlapped with the plurality of gas injecting ports 23.

The plurality of hole portions 25 do not pass through the plate base member 22b. For example, the plurality of hole portions 25 are holes bored from the gas injecting surface 22s toward the inside of the plate base member 22b. On the shower plate 22, surface areas of the plurality of hole portions 25 are configured so as to be increased radially gradually from a center 22c of the gas injecting surface 22s.

A thickness of the plate base member 22b is 5 mm to 50 mm inclusive. As an example, the thickness of the plate base member 22b is 25 mm. An inner diameter of each of the plurality of gas injecting ports 23 is smaller than an inner diameter of each of the plurality of hole portions 25. The inner diameter of each of the plurality of gas injecting ports 23 is 0.3 mm to 1 mm inclusive. The inner diameters of the plurality of gas injecting ports 23 are the same. As an example, the inner diameter of each of the plurality of gas injecting ports is 0.7 mm.

The plate base member 22b and the head body 21 include a conductor such as aluminum (Al), an aluminum alloy, and stainless steel. The plate base member 22b and the head body 21 may be subjected to an oxide coating process when necessary in order to enhance corrosion resistance.

The support 30 can support the substrate 80. The support 30 faces the shower plate 22. A substrate placement surface, on which the substrate 80 is placed, of the support 30 is substantially parallel with the shower plate 22. The support 30 has a configuration including a conductor, for example. The surface on which the substrate 80 is placed may be a conductor or an insulation body on the support 30. For example, electrostatic chuck may be provided on the surface on which the substrate 80 is placed on the support 30. In the case where the support 30 includes the insulation body and the electrostatic chuck, even when the support 30 is grounded, a parasitic capacitance 31 is generated between the substrate 80 and a ground.

To the support 30, a power supply means 55 may be connected so as to be capable of supply bias power to the substrate 80. The power supply means 55 may be an AC power supply (high frequency power supply) or a DC power supply, for example. For example, in the case where vacuum processing apparatus 1 is used as an etching apparatus such as RIE, the power supply means 55 inputs power to the substrate 80, and a bias potential is applied to the substrate 80. Further, a temperature adjustment mechanism which heats or cools the substrate 80 to a predetermined temperature may be incorporated in the support 30. A distance between the support 30 and the shower plate 22 (hereinafter, referred to as distance between electrodes) is 10 mm to 30 mm inclusive. As an example, the distance between electrodes is 20 mm.

On the support 30, a planar shape of the placement surface on which the substrate 80 is placed corresponds to a planar shape of the substrate 80. Also, a planar shape of the shower plate 22 corresponds to a planar shape of the placement surface. For example, in the case where the substrate 80 is a rectangular substrate applied to a panel or the like, the planar shape of the placement surface and the shower plate 22 is a rectangle. In the case where the substrate 80 is a wafer substrate applied to a semiconductor device or the like, the planar shape of the placement surface and the shower plate 22 is a circle. In this embodiment, as an example, an assumption is made that the planar shape of the placement surface and the shower plate 22 is a rectangle. An area of the placement surface and the shower plate 22 is larger than an area of the substrate 80. Moreover, the substrate 80 is, for example, a glass substrate having a thickness of 0.5 mm. A size of the substrate 80 is, for example, 1500 mm*1300 mm or more.

The gas supply source 40 supplies a process gas (film deposition gas, etching gas, or the like) to the inner space 28 of the shower head 20. The gas supply source 40 includes a flowmeter 41 and the gas introduction tube 42. A flow rate of the process gas in the gas introduction tube 42 is adjusted by the flowmeter 41.

The power supply means 50 includes a power supply 51, a matching circuit unit (matching box) 52, and a wiring 53. The wiring 53 is connected to the center of the shower head 20. The matching circuit unit 52 is put between the shower head 20 and the power supply 51. The power supply 51 is an RF power supply, for example. The power supply 51 may be a VHF power supply. Further, the power supply 51 may be a DC power supply. In the case where the power supply 51 is the DC power supply, the matching circuit unit 52 is removed from the power supply means 50.

For example, when the process gas is introduced from the shower head 20 to the plasma forming space 10p, and power is input from the power supply 51 to the shower head 20 through the wiring 53, discharge plasma is generated in the plasma forming space 10p. For example, in the case where the film deposition gas is introduced to the plasma forming space 10p, and film formation plasma is generated in the plasma forming space 10p, a film is formed on the substrate 80. In this case, the vacuum processing apparatus 1 functions as the film deposition apparatus. On the other hand, in the case where the etching gas is introduced in the plasma forming space 10p, and etching plasma is generated in the plasma forming space 10p, the film is removed from the substrate 80. In this case, the vacuum processing apparatus 1 functions as the etching apparatus.

Before describing a function of the vacuum processing apparatus 1 described above, a function of a vacuum processing apparatus according to a comparison example will be described. The vacuum processing apparatus according to the comparison example has a configuration in which the hole portions 25 are not provided in the shower plate 22.

In the comparison example, as the size of the substrate 80 is increased, a greater in-plane variation of the plasma density is caused. As a result, there is a possibility that in-plane variation of the film quality (film thickness, film stress, or the like) of a film formed by plasma CVD may become greater. Further, at a time of etching, there is a possibility that in-plane variation of etching rate may become greater.

In a capacitance coupling method, high-frequency power is applied from the power supply 51 to the cathode (shower head). However, the high frequency supplied from the power supply 51 to the shower head is not transmitted through an inside of the conductor that constitutes the shower head but is transmitted on a surface of the conductor and propagated to shower plate (skin effect).

To one arbitrary point on the shower plate, electromagnetic waves are propagated from an arbitrary direction. As a result, at the one arbitrary point, electromagnetic waves having a plurality of phases are synthesized. However, depending on positions on the shower plate, synthesis of the electromagnetic waves differs, and standing waves may be generated on the shower plate in some cases.

As a result, a voltage distribution is caused within a plane of the shower plate. This phenomenon is markedly caused, as a frequency becomes higher, or the area of the shower plate becomes larger. For example, the power applied to the shower plate may be the highest in the vicinity of the center of the shower plate, and a voltage in the vicinity of end portions of the shower plate may be the lowest in some cases. In particular, in the case where the planar shape of the shower plate is a rectangle, the power applied to the shower plate tends to be the highest in the vicinity of the center of the shower plate, and the voltage in the vicinity of four corners thereof tends to be the lowest.

Thus, in the comparison example, discharge current is concentrated on the vicinity of the center where the voltage is the highest, and the plasma density in the vicinity of the center is the highest. Accordingly, in the comparison example, more radicals are generated in the vicinity of the center of the shower plate, and higher ion energy is generated in the vicinity of the center of the shower plate. As a result, in the comparison example, the in-plane variations of the film quality (film thickness, film stress, or the like) of the film formed on the substrate and the etching rate become greater.

In the case where the size of the substrate is relatively small (for example, 920*730 mm or less), there is a case where the in-plane variation of the plasma density as described above may be negligible. However, as the size of the substrate becomes larger (for example, 920*730 mm or more), the in-plane variation of the plasma density is not negligible.

As a method of coping with the phenomenon as described above, there is a method of changing the deposition conditions such as a discharge power, a gas flow rate, a flow ratio, a discharge pressure, and a distance between the cathode and anode. However, conducting this method may result in causing the deposition rate to be slow down or not improving a film stress distribution, although a film thickness distribution is improved. Eventually, the in-plane variation of the plasma density cannot be improved by this method.

In contrast, in this embodiment, the plurality of hole portions 25 are provided on the gas injecting surface 22s of the shower plate 22 in addition to the plurality of gas injecting ports 23. Further, the depth of the plurality of hole portions 25 is gradually changed from the center 22c toward an end portion 22e. For example, in the vicinity of the center 22c where the voltage is the highest on the shower plate 22 at a time of inputting the power, the hole portions 25 are not provided. Further, in the vicinity of the end portion 22e where the voltage is the lowest on the shower plate 22 at a time of inputting the power, the deepest hole portions 25 are disposed.

With this configuration, an effective surface area (surface area per unit area) of the gas injecting surface 22s on the shower plate 22 is gradually increased from the center 22c toward the end portion 22e. As a result, discharge is likely to occur as compared to the vicinity of the center in the vicinity of the end portion where depths of the hole portions 25 are deepest. The in-plane variation of the plasma density due to a voltage distribution held by the shower plate 22 is corrected by the disposition of the hole portions 25, and thus the plasma density is uniform within the plane of the shower plate 22.

Moreover, by the capacitance coupling method, as the discharge frequency is higher, the plasma density becomes higher, so ion damage tends to be low. Therefore, in a viewpoint of the enhancement of productivity and the achievement of high film quality, for example, it is desirable that the discharge frequency be 27.12 MHz rather than 13.56 MHz. However, when the discharge frequency is higher, a greater in-plane variation of the film quality (film thickness, film stress) is caused.

On the other hand, when the discharge frequency is set to be a lower frequency than 13.56 MHz, or a DC discharge is adopted, ion energy becomes too strong. This may cause the film quality and etching characteristics to deteriorate. For this reason, as the discharge frequency, 13.56 MHz is selected in this embodiment.

Subsequently, a specific example of an function of the shower plate 22 according to this embodiment will be described below.

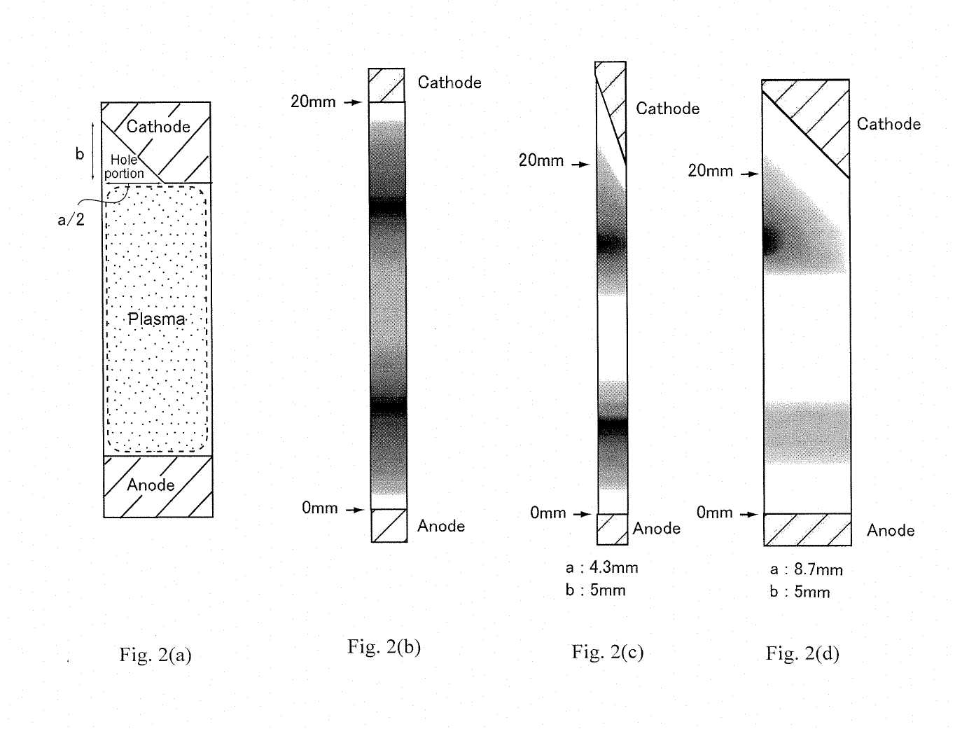

FIG. 2(a) is a schematic cross sectional view showing a plasma analysis model of a plasma analysis according to this embodiment. FIGS. 2(b) to 2(d) each are a schematic cross sectional view showing a plasma analysis result and a graph showing the plasma density according to this embodiment.

In the plasma analysis model shown in FIG. 2(a), in a cathode corresponding to the shower plate 22, a conical hole portion is disposed. The distance between electrodes between an anode corresponding to the substrate 80 and the cathode is 20 mm. Between the anode and the cathode, nitride gas having a pressure of 300 Pa exists. A frequency of a high frequency wave is 13.56 MHz. “a/2” denotes a radius (mm) of the hole portion, and “b” denotes a depth (mm) of the hole portion.

Further, FIGS. 2(b) to 2(d) each show a degree of electron generation rate with white and black gradation. For example, in FIGS. 2(b) to 2(d), the darker the black color, the higher the electron generation rate (/m³/sec) becomes. The electron generation rate depends on a discharge voltage, for example. The lower the discharge voltage, the lower the electron generation rate becomes. Thus, a radical generation rate and ion irradiation energy as factors for deciding the deposition rate, the film stress, and the etching rate are lowered.

FIG. 2(b) shows the electron generation rate of the cathode having no hole portion. As shown in FIG. 2(b), on the position distanced from each of the cathode and the anode by approximately 5 mm, the electron generation rate becomes the highest.

In contrast, FIG. 2(c) shows the electron generation rate in the case where a hole portion having an inner diameter of 4.3 mm and a depth of 5 mm is formed on the cathode. On the position by approximately 5 mm distanced from each of the cathode and the anode, the electron generation rate is higher. But, in the example of FIG. 2(c), in the vicinity of the center of the hole portion on the cathode side, the electron generation rate is relatively high. That is, it is found that the state of plasma discharge is changed by forming the hole portion on the cathode in the example of FIG. 2(c).

FIG. 2(d) shows the electron generation rate in the case where a hole portion having an inner diameter of 8.7 mm and a depth of 5 mm is formed on the cathode. In this condition, electrons are unlikely to be generated on the anode side but be preferentially generated in the vicinity of the center of the hole portion on the cathode side. The form of the discharge is significantly different from those shown in FIG. 2(b) and FIG. 2(c). In FIG. 2(d), it is estimated that a hollow effect is generated in the hole portion.

In the case where the hollow effect is generated, substantially no electron generation is caused on the anode side, so ions are difficult to be generated in the vicinity of the anode. Thus, ion irradiation toward the anode (substrate) side is reduced, and it becomes difficult to control the film stress with the ion irradiation to the substrate as the decision factor of the film stress. For this reason, the hole portions 25 having the inner diameter of approximately 4 mm, which do not cause the hollow effect, are provided on the shower plate 22 in this embodiment. For example, the hole portions 25 having the inner diameter of 3.5 mm are formed on the gas injecting surface 22s of the shower plate 22.

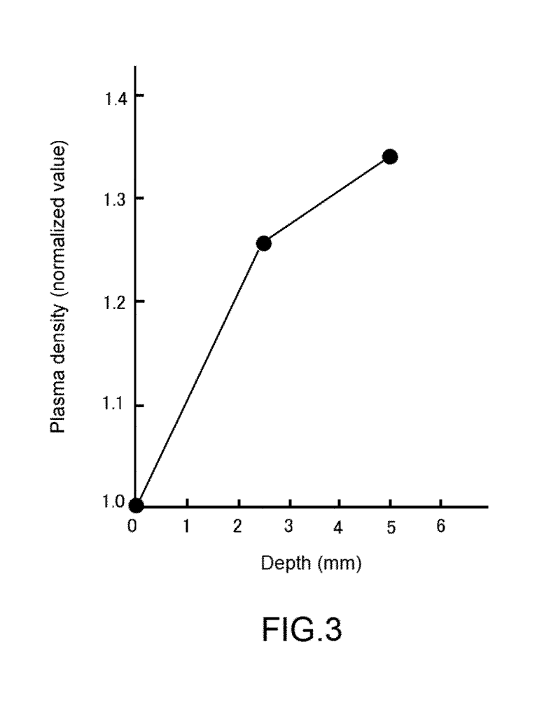

FIG. 3 is a graph showing a relationship between the depth of the hole portion and the plasma density according to this embodiment.

For example, in the case where nitrogen gas is used as the discharge gas, when the depth of the hole portions 25 is 2.5 mm, it is found that the plasma density is 1.25 times or more as compared to the case where hole portions 25 are not formed. Further, when the depth of the hole portion is 5 mm, it is found that the plasma density is 1.3 times or more as compared to the case where the hole portion is not formed.

From those results, when the hole portions 25 are formed on the gas injecting surface 22s on the shower plate 22, the plasma density is increased as compared to the case where the hole portions 25 are not formed on the gas injecting surface 22s. Further, as the depth of the hole portions 25 is increased, the plasma density is higher. That is, as the surface area of the hole portions 25 on the gas injecting surface 22s is increased, the plasma density is higher. It is considered that the number of secondary electrons discharged from the hole portions 25 is increased, as the surface area of the hole portions 25 is increased, as an example.

With the use of the shower plate 22 as described above, the in-plane variation of the plasma density on the shower plate 22 can be more uniformly controlled by adjusting the depth of the hole portions 25 disposed on the shower plate 22.

Hereinafter, the disposition of the plurality of hole portions 25 provided on the shower plate 22 will be described.

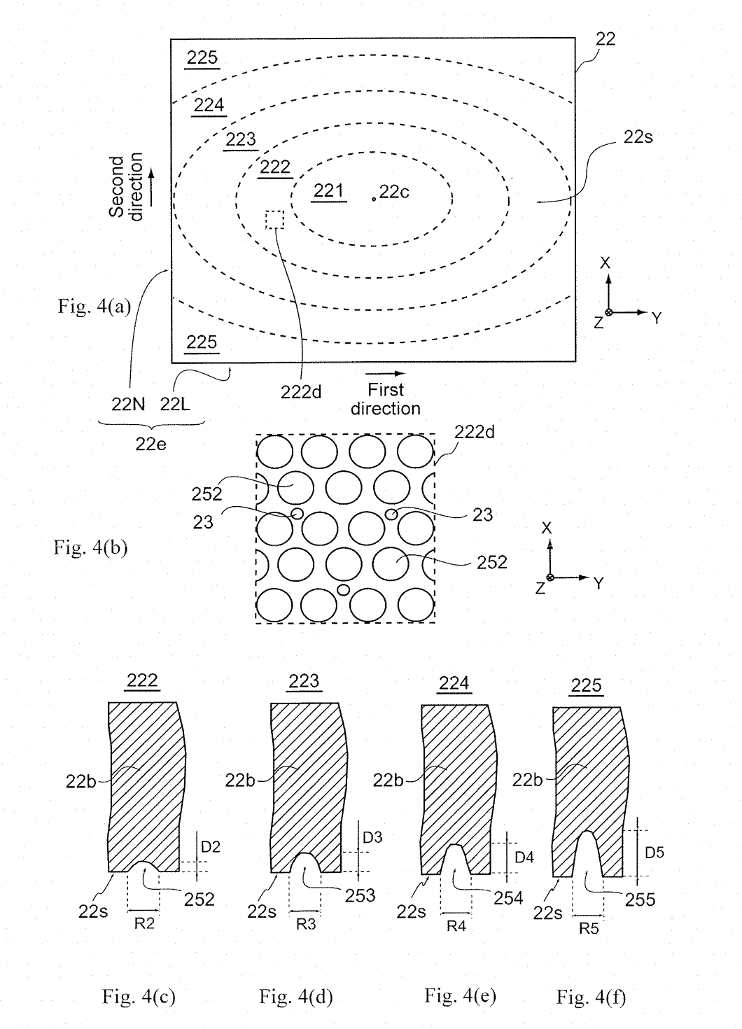

FIG. 4(a) is a schematic plan view showing the shower plate according to this embodiment. FIG. 4(b) is a schematic plan view showing a region surrounded by a broken line 222d of FIG. 4(a). FIGS. 4(c) to 4(f) are schematic cross sectional views each showing the hole portion on the shower plate according to this embodiment.

When a n electric field intensity distribution of the shower plate 22 is analyzed by electromagnetic analysis, it is found that the electric field intensity is larger toward the center 22c, and the electric field intensity is smaller toward the end portion 22e. Further, contour lines (lines formed of a group of points of the same electric field intensity) of the electric field intensity within the plane of the shower plate 22 are concentrically elliptic shapes, for example.

For example, as shown in FIG. 4(a), a disposition region of the hole portions 25 disposed on the shower plate 22 is sectioned into a plurality of regions on the basis of the electric field intensities. For example, the gas injecting surface 22s has a center region 221 and a plurality of regions 222, 223, 224, and 225 disposed concentrically with respect to the center region 221. For example, the center region 221 is surrounded by the region 222, the region 222 is surrounded by the region 223, and the region 223 is surrounded by the region 224. Further, the region 224 is surrounded by the region 225.

The planar shape of the shower plate 22 according to this embodiment is a rectangle, as an example. Here, a direction parallel to a long end portion 22L of the shower plate 22 is treated as a first direction (Y axis direction), and a direction parallel to a short end portion 22N of the shower plate 22 is treated as a second direction (X axis direction). The second direction is orthogonal to the first direction. In the center region 221 and the plurality of regions 222, 223, and 224, a diameter in the first direction is longer than a diameter in the second direction. For example, outlines of the center region 221 and the plurality of regions 222 and 223 are elliptic shapes. In other words, boundaries for sectioning the center region 221 and the plurality of regions 222 and 223 are elliptic shape (for example, a long axis is double of a short axis).

Here, the region 224 is not a continuous region, which is cut on the short end portion 22N of the shower plate 22. However, when a virtual line which continuously links the outline of the region 224 is drawn, the outline of the virtual line is an elliptic shape. Further, the region 225 is a region outside the region 224 on the gas injecting surface 22s.

The plurality of gas injecting ports 23 and the plurality of hole portions 25 are disposed on each of the center region 221 and the plurality of regions 222, 223, 224, and 225. In this case, the hole portions 25 are a generic term of hole portions 252, 253, 254, and 255 to be described later. Moreover, in an example of FIG. 4(a), the hole portions 25 are not disposed on the center region 221.

For example, FIG. 4(b) shows a flat plane of a region surrounded by the broken line 222d on the region 222. As shown in FIG. 4(b), the plurality of hole portions 252 are disposed on the gas injecting surface 22s in a honeycomb pattern. The gas injecting port 23 is disposed on the center of a triangle with the centers of three hole portions 252 adjacent with one another as apexes, for example.

However, the surface areas of the hole portions 25 provided on the gas injecting surface 22s are different depending on the plurality of regions 222, 223, 224, and 225. For example, in two regions adjacent to each other, the surface area of each of the plurality of hole portions 25 disposed on a region opposite to the center region 221 is larger than the surface area of each of the plurality of hole portions 25 disposed on a region on the center region 221 side.

For example, as shown in FIGS. 4(c) to 4(f), the surface area of the hole portion 253 disposed on the region 223 on an outer side of the region 222 is larger than the surface area of the hole portion 252 disposed on the region 222. The surface area of the hole portion 254 disposed on the region 224 on an outer side of the region 223 is larger than the surface area of the hole portion 253 on the region 223. The surface area of the hole portion 255 disposed on the region 225 on an outer side of the region 224 is larger than the surface area of the hole portion 254 on the region 224.

Here, an inner diameter of each of the plurality of hole portions 25 disposed on an opposite region of the center region 221 is the same as an inner diameter of each of the plurality of hole portions 25 disposed on the region on the center region 221 side. For example, an inner diameter R3 of the hole portion 253 disposed on the region 223 on the outer side of the region 222 is the same as an inner diameter R2 of the hole portion 252 disposed on the region 222. An inner diameter R4 of the hole portion 254 disposed on the region 224 on the outer side of the region 223 is the same as the inner diameter R3 of the hole portion 253 disposed on the region 223. An inner diameter R5 of the hole portion 255 disposed on the region 225 on the outer side of the region 224 is the same as the inner diameter R4 of the hole portion 254 disposed on the region 224. That is, the inner diameters R2, R3, R4, and R5 are the same. Moreover, the inner diameters R2, R3, R4, and R5 are the inner diameter on the position on the gas injecting surface 22s.

In the shower plate 22 of this embodiment, the surface areas of the hole portions 25 disposed on the plurality of regions 222, 223, 224, and 225 are varied by changing the depths. For example, the depth of each of the plurality of hole portions 25 disposed on a region opposite to the center region 221 is deeper than the depth of each of the plurality of hole portions 25 disposed on a region on the center region 221 side. A depth D3 of the hole portion 253 disposed on the region 223 on the outer side of the region 222 is deeper than a depth D2 of the hole portion 252 disposed on the region 222. A depth D4 of the hole portion 254 disposed on the region 224 on the outer side of the region 223 is deeper than the depth D3 of the hole portion 253 disposed on the region 223. A depth D5 of the hole portion 255 disposed on the region 225 on the outer side of the region 224 is deeper than the depth D4 of the hole portion 254 disposed on the region 224.

Here, when the inner diameter is increased without changing the depths to increase the surface areas of the hole portions 25, occupied areas of the hole portions 25 on the gas injecting surface 22s are increased. As a result, in the region where the inner diameter of the hole portions 25 is set to be wider, a disposition density of the plurality of hole portions 25 becomes lower, or the hole portions 25 and the gas injecting ports 23 are interfered with each other.

As the depths of the hole portions 25 are deeper, the length of the gas injecting port 23 becomes shorter, if the hole portions 25 and the gas injecting ports 23 are overlapped. This causes a change in conductance of the gas injecting ports 23 for each of the regions 222, 223, 224, and 225, and thus the gas flow rate is different among the regions 222, 223, 224, and 225.

Further, the inner diameter of the hole portions 25 is smaller than a pitch of the gas injecting ports 23 on the shower plate 22. When the inner diameter of the hole portions 25 is larger than the pitch of the gas injecting ports 23, the number of gas injecting ports 23 is decreased. When the number of gas injecting ports 23 is decreased, the gas flow rate per gas injecting port 23 is increased, and the gas flow rate distribution on the gas injecting surface 22s is likely to be affected by a variation in sizes of the gas injecting ports 23. Further, a pattern of the gas injecting ports 23 is reflected on the film thickness distribution.

Further, when the inner diameter of the hole portions 25 is increased, and the surface area of the hole portions 25 is increased, a hollow cathode discharge is caused, or an abnormal discharge is caused in the hole portions 25. Thus, the plasma density may be locally increased. Alternatively, when the hollow cathode discharge is caused, or the abnormal discharge is caused in the hole portions 25, a film adhered on the shower plate 22 is easily peeled off. For this reason, the surface areas of the hole portions 25 on the plurality of regions 222, 223, 224, and 225 are changed by not changing the inner diameter but changing the depths in this embodiment.

The size of the shower plate 22 is equal to or more than 1500 mm*1300 mm. As an example, in the case where the size of the substrate 80 is 1850 mm*1500 mm, the size of the shower plate 22 is 2000 mm*1700 mm. The pitch of the gas injecting ports 23 on the gas injecting surface 22s is approximately ½ of the distance between electrodes. On the shower plate 22 (size: 2000 mm*1700 mm), approximately 52000 gas injecting ports 23 are disposed, and approximately 200000 hole portions 25 are disposed.

Moreover, in the case where the planar shape of the substrate 80 and the support 30 is a circular shape, in accordance with this shape, the planar shape of the shower plate 22 becomes also a circular shape. In this case, the planar shape of each of the center region 221 and the plurality of regions 222, 223, 224, and 225 is a circular shape.

Further, the plurality of hole portions 25 may be disposed also in the center region 221. In this case, the surface area of each of the plurality of hole portions 25 disposed on the center region 221 is set to be smaller than the surface area of each of the plurality of hole portions 25 disposed on the region 222 adjacent to the center region 221.

Further, in this embodiment, the circular shape is exemplified as the planar shape of the plurality of hole portions 25, but is not limited to this example. The planar shape of the plurality of hole portions 25 may be a rectangular shape or an elliptic shape.

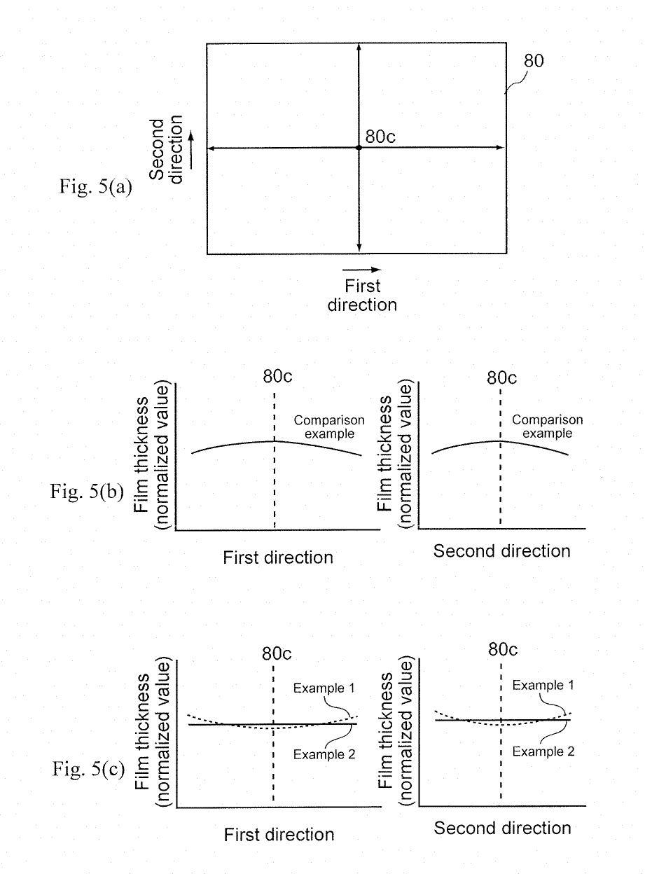

FIG. 5(a) is a schematic plan view of the substrate on which a film is formed by the substrate processing apparatus according to this embodiment. FIG. 5(b) is a schematic graph showing a film thickness distribution of a film according to a comparison example. FIG. 5(c) is a schematic graph showing a film thickness distribution of the film according to this embodiment.

The substrate 80 shown in FIG. 5(a) is a glass substrate. In the substrate 80, for example, a length of the first direction is 1850 mm, and a length of the second direction is 1500 mm. FIGS. 5(b) and 5(c) each show the film thickness distribution on a line which is parallel to the first direction or the second direction and is passed through a center 80c of the substrate 80. Deposition conditions are as follows. The film formed on the substrate 80 is a SiNₓ film. The SiNₓ film is formed on the substrate 80.

Deposition gas: SiH₄ (flow rate: 1.6 slm)/NH₃ (flow rate: 16 slm)

Discharge pressure: 265 Pa

Distance between shower plate and substrate: 21 mm

Discharge power: 14.5 kW (frequency: 13.56 MHz)

Substrate temperature: 350° C.

In the comparison example shown in FIG. 5(b), the hole portions 25 are not provided on the shower plate. In the comparison example, the film thickness of the center 80c of the substrate 80 is the thickest, and the film thickness is gradually thinner toward an outer circumference of the substrate 80. That is, the comparison example shows the film thickness distribution projected upwards. This corresponds to the fact that the plasma density is increased toward the center of the shower plate, and the plasma density is decreased toward the end portion of the shower plate.

In contrast, FIG. 5(c) shows results of examples 1 and 2 according to this embodiment. In the examples 1 and 2, the plurality of hole portions 25 are provided on the shower plate 22. For example, in the example 1, the depth D2 of the hole portion 252 on the region 222 is 1.5 mm, the depth D3 of the hole portion 253 on the region 223 is 3 mm, the depth D4 of the hole portion 254 on the region 224 is 4.5 mm, and the depth D5 of the hole portion 255 on the region 225 is 6 mm. In the example 1, the film thickness on the center 80c of the substrate 80 is the thinnest, and the thickness of the film thickness is increased toward the outer circumference of the substrate 80. That is, the results shown in the FIG. 5(c) indicates that the film thickness distribution is controlled by forming the plurality of hole portions 25 on the shower plate 22.

Further, in the example 2, the depth D2 of the hole portion 252 on the region 222, the depth D3 of the hole portion 253 on the region 223, the depth D4 of the hole portion 254 on the region 224, and the depth D5 of the hole portion 255 on the region 225 are set to be further shallower as compared to the respective values in the example 1. In this case, the film thickness distribution of the film formed on the substrate 80 is substantially uniform in the first direction and in the second direction.

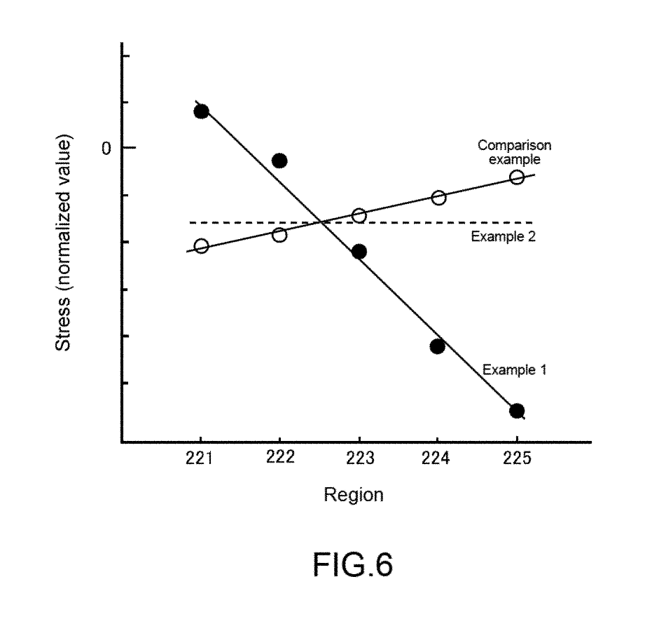

FIG. 6 is a schematic graph showing a stress distribution of the film according to this embodiment and the comparison example.

A horizontal axis shown in FIG. 6 corresponds to positions of the center region 221 and the regions 222, 223, 224, and 225. A vertical axis shown in FIG. 6 indicates a normalized value of a stress value of the SiNₓ film. The graph shown in FIG. 6 means that as an absolute value of a negative value on the vertical axis is increased, a compression stress becomes stronger, and as an absolute value of a positive value on the vertical axis is increased, a tensile stress becomes stronger.

In the comparison example, the SiNₓ film deposited on the center region 221 has a compression stress. Further, toward an outside region from the center region 221, the SiNₓ film is changed to have a tensile stress rather than the compression stress. This corresponds to the fact that the plasma density on the center region 221 is the highest, and the plasma density becomes lower toward the outside region from the center region 221 on the shower plate with no hole portion 25.

On the other hand, in the example 1, the SiNₓ film deposited on the center region 221 has the tensile stress. Further, in the example 1, on the SiNₓ film, the compression stress is stronger than the tensile stress toward the outside region from the center region 221. That is, the result shown in FIG. 6 indicates that the stress distribution is controlled by forming the plurality of hole portions 25 on the shower plate 22.

Further, on the basis of the result in the example 1, the stresses on the center region 221 and the regions 222, 223, 224, and 225 can be set to be more uniform. For example, in order to set a gradient of the line in the example 1 to be gentler, the depth D2 of the hole portions 252 on the region 222, the depth D3 of the hole portions 253 on the region 223, the depth D4 of the hole portions 254 on the region 224, and the depth D5 of the hole portions 255 on the region 225 are shallower as compared to the respective values in the example 1.

For example, in the example 2, the depth D2 of the hole portion 252 on the region 222 is set to 0.33 mm. The depth D3 of the hole portion 253 on the region 223 is set to 0.65 mm. The depth D4 of the hole portion 254 on the region 224 is set to 0.98 mm. The depth D5 of the hole portion 255 on the region 225 is set to 1.3 mm. In this case, the stresses on the center region 221 and the regions 222, 223, 224, and 225 are substantially uniform.

The depths of the hole portions 25 disposed on the respective regions are changed depending on the deposition conditions.

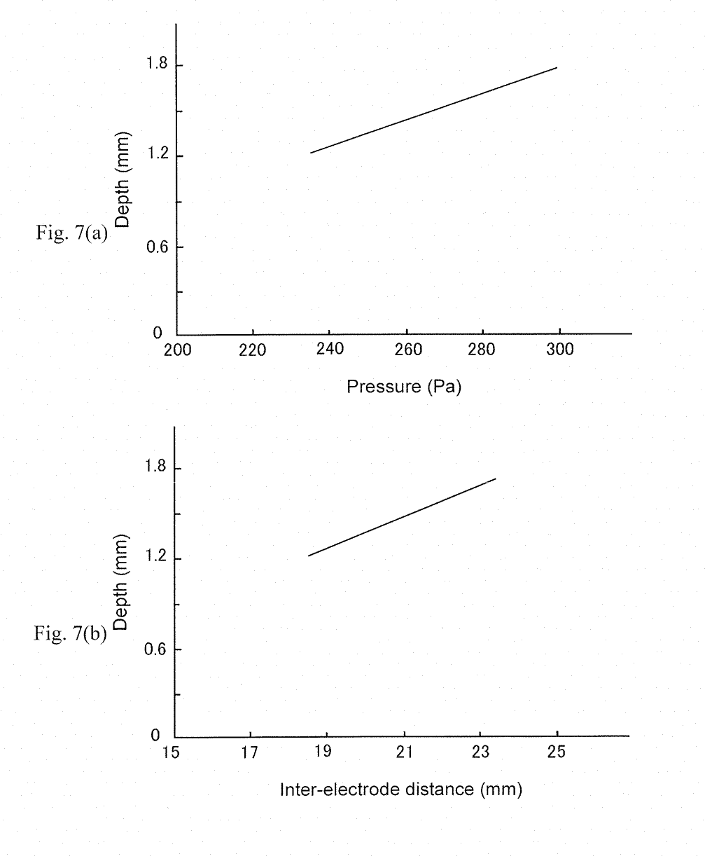

For example, FIG. 7(a) and FIG. 7(b) are schematic graphs each showing a relationship between the deposition conditions and an optimal value of the depth on the outermost region. FIG. 7(a) and FIG. 7(b) show the relationship between the deposition conditions and an optimal value of the hole portions 255 on the region 225.

For example, as shown in FIG. 7(a), the optimal value of the hole portion 255 on the region 225 is shifted to a value larger than 1.3 mm, when the discharge pressure is set to be higher than the condition described above (265 Pa). Conversely, when the discharge pressure is set to be lower than the condition described above, the optimal value of the hole portion 255 is shifted to a value smaller than 1.3 mm.

Further, as shown in FIG. 7(b), the optimal value of the hole portion 255 on the region 225 is shifted to a value larger than 1.3 mmm, when the distance between electrodes is set to be longer than the condition described above (21 mm). Conversely, when the distance between electrodes is set to be shorter than the condition described above, the optimal value of the hole portion 255 is shifted to a value smaller than 1.3 mm. In this way, the depth of the hole portion 25 disposed on each region is adjusted appropriately on the basis of the deposition conditions.

Further, the number of regions that concentrically section the gas injecting surface 22s of the shower plate 22 is not limited to five in this embodiment. For example, the number of regions that concentrically section the gas injecting surface 22s may be six or more. For example, the center region 221 and the regions 222, 223, 224, and 225 are respectively further sectioned into ten regions concentrically, and thus 50 regions that concentrically section gas injecting surface 22s may be obtained.

For example, in the example 1, a difference between the depths of the hole portions 25 on the adjacent region is 1.5 mm. In the example 1, if the number of regions that section the gas injecting surface 22s is 50, the difference between the depths of the hole portions 25 on the adjacent regions is 0.15 mm (1.5 mm/10). The difference between the depths of the hole portions 25 on the adjacent regions is further reduced. Further, in the example 2, the difference between the depths of the hole portions 25 on the adjacent regions is approximately 0.3 mm. In the example 2, if the number of regions that section the gas injecting surface 22s is 50, the difference between the depths of the hole portions 25 on the adjacent regions is 0.03 mm (0.3 mm/10). The difference between the depths of the hole portions 25 on the adjacent regions is further reduced.

As described above, by increasing the number of sectioned regions, the plasma density within the plane of the shower plate 22 is more uniform, with the result that the film quality (film thickness, stress, or the like) of the film within the plane of the substrate 80 is more uniform.

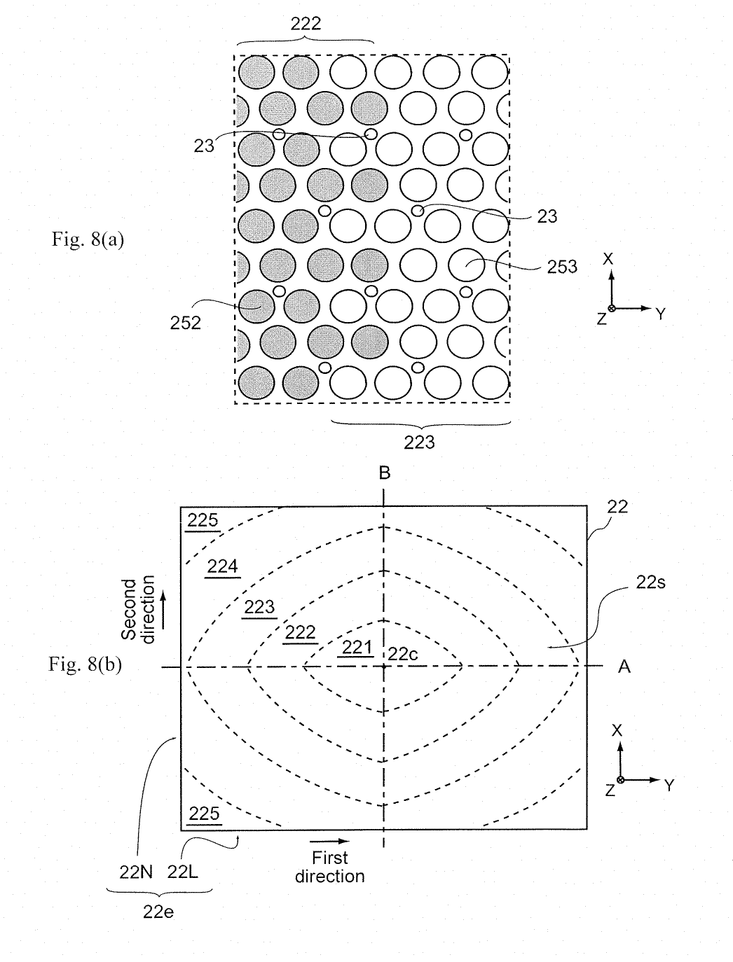

FIG. 8(a) is a schematic plan view showing another embodiment of the gas injecting surface according to this embodiment. FIG. 8(b) is a schematic plan view showing another embodiment of sectioning the shower plate according to this embodiment.

On the shower plate 22, the hole portions 25 on the respective regions may be disposed astride the adjacent regions. That is, a part of the plurality of hole portions disposed on a region opposite to the center region 221 may be disposed on a region on the center region 221 side, and a part of the plurality of hole portions 25 disposed on the center region 221 side may be disposed on the region opposite to the center region 221.

For example, FIG. 8(a) shows an example of the region 222 and the region 223 adjacent to the region 222. In this case, the region 222 is disposed on the center region 221 side, and the region 223 is disposed on an opposite side to the center region 221. Further, in FIG. 8(a), in order to clearly show the hole portions 252 and the hole portions 253, the hole portions 252 are grayed. As shown in FIG. 8(a), the part of the plurality of hole portions 253 on the region 223 is disposed on the region 222 on the center region 221 side. Further, the part of the plurality of hole portions 252 on the region 222 is disposed on the region 223.

With this disposition, the difference between the depths of the hole portions 25 on the adjacent regions is further reduced, and thus the plasma density within the plane of the shower plate 22 is more uniform. As a result, the film quality (film thickness, stress, or the like) of the film within the plane of the substrate 80 is more uniform.

Further, the optimal shape of the boundaries that section the regions is not limited to the elliptic shape. For example, in an example shown in FIG. 8(b), at an intersection of a line A which is parallel to the first direction and includes the center 22c and the boundaries that section the regions, the boundaries are bent. Further, at an intersection of a line B which is parallel to the second direction and includes the center 22c and the boundaries that section the regions, the boundaries are bent.

The planar shape of the boundaries as described above is determined on the basis of the planar shape of the shower plate 22 and an electromagnetic analysis according to the discharge condition. As a result, the in-plane variation of the plasma density on each of the center region 221 and the regions 222, 223, 224, and 225 is more uniform.

As described above, in the shower head 20 according to this embodiment, the plurality of hole portions 25, the surface areas of which are radially gradually increased from the center 22c of the gas injecting surface 22s, are provided on the gas injecting surface 22s on the shower plate 22 in addition to the plurality of gas injecting ports 23. As a result, the in-plane variation of the plasma density is more uniform by using the shower head 20. Thus, the in-plane distribution of the film quality (film thickness, film stress) of the film formed on the substrate 80 and the in-plane distribution of the etching rate are improved. In particular, as the size of the substrate 80 is increased, the shower head 20 more effectively functions.

The embodiment of the present technology is described above, but the present technology is not limited to the above embodiment and can of course be variously changed.

### REFERENCE SIGNS LIST

1 vacuum processing apparatus
10 vacuum chamber
10h gas exhaust port
10p plasma forming space
11 support portion
12 lid portion
20 shower head
21 head body
22 shower plate
22c center
22b plate base member
22e end portion
22s gas injecting surface
22c center
22L long end portion
22N short end portion
23 gas injecting port
25, 252, 253, 254, 255 hole portion
27 insulation member
28 inner space
30 support
31 capacitance
40 gas supply source
41 flowmeter
42 gas introduction tube
50, 55 power supply means
51 power supply
52 matching circuit unit
53 wiring
80 substrate
80c center
221 center region
222, 223, 224, 225 region
222d broken line

1. A shower head, comprising:
a head body having an inner space; and
a shower plate including a plurality of gas injecting ports, a gas injecting surface, and a plurality of hole portions, the plurality of gas injecting ports being communicated with the inner space, gas being injected from the plurality of gas injecting ports on the gas injecting surface, the plurality of hole portions being disposed on the gas injecting surface, and surface areas of the plurality of hole portions being radially gradually increased from a center of the gas injecting surface.

2. The shower head according to claim 1, wherein
the gas injecting surface includes a center region and a plurality of regions disposed concentrically with respect to the center region and surround the center region, and
in two of the regions adjacent to each other, the surface area of each of the plurality of hole portions disposed on the region opposite to the center region is larger than the surface area of each of the plurality of hole portions disposed on the region on the center region side.

3. The shower head according to claim 2, wherein
an inner diameter of each of the plurality of hole portions disposed on the region opposite to the center region is the same as an inner diameter of each of the plurality of hole portions disposed on the region on the center region side.

4. The shower head according to claim 2, wherein
a depth of each of the plurality of hole portions disposed on the region opposite to the center region is deeper than a depth of each of the plurality of hole portions disposed on the region on the center region side.

5. The shower head according to claim 2, wherein
the center region further includes a plurality of hole portions, and
a surface area of each of the plurality of hole portions disposed on the center region is smaller than a surface area of each of the plurality of hole portions disposed on the region adjacent to the center region.

6. The shower head according to claim 2, wherein
a part of the plurality of hole portions disposed on the region opposite to the center region is disposed on the region on the center region side, and
a part of the plurality of hole portions disposed on the region on the center region side is disposed on the region opposite to the center region.

7. A vacuum processing apparatus, comprising:
a vacuum chamber capable of maintaining a depressurized state;
a shower head including a head body having an inner space and a shower plate including a plurality of gas injecting ports, a gas injecting surface, and a plurality of hole portions, the plurality of gas injecting ports being communicated with the inner space, gas being injected from the plurality of gas injecting ports on the gas injecting surface, and the plurality of hole portions being disposed on the gas injecting surface, and surface areas of the plurality of hole portions being radially gradually increased from a center of the gas injecting surface; and
a support facing the shower head and capable of supporting a substrate.
